(19) United States
(12) Patent Application Publication
(10) Pub. No.: US 2026/0296882 A1
(43) Pub. Date: Oct. 1, 2026

(54) METHOD FOR MANUFACTURING A MICROELECTROMECHANICAL COMPONENT, AND MICROELECTROMECHANICAL COMPONENT

(71) Applicant: Robert Bosch GmbH, Stuttgart (DE)

(72) Inventors: Marcus Pritschow, Nuertingen (DE); Raphael Schuler, Tuebingen (DE)

(21) Appl. No.: 19/479,632

(22) PCT Filed: Feb. 20, 2024
(86) PCT No.: PCT/EP2024/054250

§ 371 Date: Oct. 28, 2025

(30) Foreign Application Priority Data
May 10, 2023 (DE) 10 2023 204 321.1

(51) Int. Cl. B81C 1/00; B81B 7/04

(52) U.S. Cl. CPC B81C 1/00904; B81B 7/04; B81B 2201/042; B81C 2201/0105; B81C 2201/013; B81C 2201/016; B81C 2201/0191; B81C 2201/0197

(57) ABSTRACT

A method for manufacturing a microelectromechanical component. A carrier substrate having a first surface is provided. An insulation layer is applied to the first surface before a first silicon layer grows on the insulation layer. The first silicon layer is structured in order to form at least two first peripherally extending trenches in the first silicon layer The first trenches extend through the first silicon layer (150e) at least in places. The first silicon layer is passivated, wherein the first trenches are filled and a first passivation layer forms on a side facing away from the first surface. The first passivation layer is structured. A first peripherally extending sacrificial region is formed in the first silicon layer between the first trenches and the first sacrificial region is free of the first passivation layer, at least in places, on a side facing away from the carrier substrate.

### FIELD

The present invention relates to a method for manufacturing a microelectromechanical component. The present invention also relates to a microelectromechanical component which, in particular, is manufactured using the method of the present invention.

### BACKGROUND INFORMATION

A method for manufacturing microelectromechanical structures in a layer sequence is described in Germany Patent Application No. DE 10 2015 206 996 A1.

An object of the present invention is to develop a method for manufacturing a microelectromechanical component in which the microelectromechanical component can also be separated from the layer sequence.

### SUMMARY

To achieve the object, a method for manufacturing a microelectromechanical component, in particular a semiconductor component, is provided according certain features of the present invention. Furthermore, a microelectromechanical component which in particular is manufactured according to the manufacturing method of the present invention is provided according to certain features of the present invention.

According to an example embodiment of the present invention, in the method for manufacturing a microelectromechanical component, in particular a semiconductor component, a carrier substrate having a first surface is first provided. An insulation layer is applied to the first surface and then a first silicon layer grows, in particular epitaxially, on the insulation layer. Furthermore, the first silicon layer is structured in order to form at least two first peripherally extending trenches in the first silicon layer. The first trenches extend through the first silicon layer at least in places. In addition, the first silicon layer is passivated. Here, the first trenches are filled with a first passivation layer and a first passivation layer is formed on a side of the first silicon layer facing away from the first surface. Furthermore, the first passivation layer is structured. Here, a first peripherally extending sacrificial region is formed in the first silicon layer between the first trenches. In a plan view of the first silicon layer, the first sacrificial region accordingly frames a functional region of the first silicon layer within the surrounding first sacrificial region. The first sacrificial region is free of the passivation layer, at least in places, on a side, in particular of the first silicon layer, facing away from the carrier substrate.

Subsequently, the process is repeated with growing, in particular epitaxial growing, structuring and passivating for a second silicon layer arranged on the first silicon layer, so that at least two second peripherally extending trenches filled with a second passivation layer are produced and a second sacrificial region between the second trenches is produced. In particular, the second silicon layer is arranged directly on the first silicon layer. Alternatively, the second silicon layer is arranged on the first silicon layer at a distance from the first silicon layer. In particular, the first and second silicon layers are the same silicon layers. Alternatively, the first and second silicon layers are different from one another, in particular chemically. All sacrificial regions, in particular the first sacrificial region and the second sacrificial region, form a contiguous, in particular common, sacrificial region. This means that the individual sacrificial regions are connected to each other at least in places. In addition, the microelectromechanical component is produced within a functional region of the silicon layers which is at least partly surrounded by the contiguous sacrificial region. The microelectromechanical component is in particular at least one MEMS component, in particular actuator, the manufacturing tolerances of which are very small and which, after being separated, is placed tightly relative to other sensors, in particular structurally identical sensors, in a sensor arrangement. In a further method step, the contiguous sacrificial region is removed so that the microelectromechanical component is at least partly detached from the silicon layers, in particular on the opposite side of the contiguous sacrificial region. The contiguous sacrificial region is removed in particular by plasma-free and/or plasma-assisted etching. The method thus makes it possible for a microelectromechanical component manufactured within a layer sequence, in particular silicon layer sequence, to be at least partly separated very precisely in comparison with the conventional sawing method, for example.

According to an example embodiment of the present invention, preferably, the process is repeated with the growing, in particular epitaxial growing, structuring and passivating for at least one additional, in particular third, silicon layer, which is arranged on the first silicon layer and the second silicon layer, so that at least two additional, in particular third, peripherally extending trenches filled with at least one additional, in particular third, passivation layer are produced and at least one additional, in particular third, sacrificial region is produced. The plurality of layers stacked one on top of the other make possible, in particular, a diverse design of the contiguous sacrificial region and in particular of the manufactured microelectromechanical component.

Preferably, the silicon layers and the passivation layers are structured such that at least one of the sacrificial regions, in particular first, second or additional sacrificial regions, has a main extension plane in the longitudinal direction and at least partly overlaps, in particular outside of the contiguous sacrificial region, with the silicon layer lying therebelow and/or the silicon layer lying thereabove. The term “longitudinal direction” refers in particular to a direction that runs parallel to the silicon layer in the direction of the functional region having the microelectromechanical component. This provides the possibility of very precisely producing at least one step, in particular horizontally extending step, in the separation edge of the microelectromechanical component. Preferably, the silicon layers and the passivation layers are structured here such that the at least one sacrificial region having the main extension plane in the longitudinal direction changes direction, in particular by 180°, relative to the microelectromechanical component after a first part, in particular after half, of the peripheral extent, so that, after the contiguous sacrificial region has been removed, the microelectromechanical component has, in the first part of the peripheral extent, an outwardly protruding first frame region and, in a second part of the peripheral extent, a step-shaped second frame region. This provides the possibility of giving the separation edge of the microelectromechanical component different step-shaped forms on different sides of the microelectromechanical component. The term “peripheral extent” refers here in particular to the course of the sacrificial region around the functional region having the microelectromechanical component in a plan view of the layer stack. The sacrificial region can extend peripherally around the functional region in a silicon layer circularly, hexagonally or in a quadrilateral shape, for example. The term “frame regions” refers in particular to regions of the microelectromechanical component in which no sensitive microstructures of the microelectromechanical component are arranged and which at least partly frame the microelectromechanical component. Preferably, the microelectromechanical component is detached from the silicon layers surrounding the microelectromechanical component and, by means of a tool which engages with the first frame region and the second frame region of the microelectromechanical component, the second frame region being arranged at a different height than the first frame region, is placed on a substrate. The engaging tool is in particular a vacuum gripper. It is also preferred that the microelectromechanical component is placed on the substrate relative to a structurally identical second microelectromechanical component in such a way that the frame regions of the two microelectromechanical components at least partially overlap. A first frame region of a microelectromechanical component thus always lies on a second frame region of a structurally identical microelectromechanical component and thus overlaps with it. Thus, space is saved in the arrangement of the microelectromechanical components with respect to one another, and in addition the microelectromechanical components are already aligned with one another.

According to an example embodiment of the present invention, preferably, the microelectromechanical component is also produced, at least in part, by the manufacturing process described above. In this context, there is in particular again the structuring and passivating of at least one of the silicon layers, as well as the structuring of at least one of the associated passivation layers and the removal of the sacrificial regions formed. Thus, the separating and manufacturing of the microelectromechanical component can occur in the same process.

Preferably, the passivation layers and silicon layers are structured such that, after the contiguous sacrificial region has been removed, the microelectromechanical component is partly connected, by means of at least one bridge, to the silicon layers surrounding the microelectromechanical component. This at least one bridge ensures that the microelectromechanical component cannot fall out of the layer sequence. Alternatively, the passivation layers and silicon layers are structured such that, after the contiguous sacrificial region has been removed, the microelectromechanical component is completely detached from the silicon layers surrounding the microelectromechanical component. Thus, an additional process step for separating the microelectromechanical component is no longer necessary.

Preferably, the microelectromechanical component is produced such that it is at least partly directly connected to the contiguous sacrificial region. The described process allows for very precise separation of the microelectromechanical component with few defects, such as cracks or particles due to the separation edge. This also provides the possibility of at least partly directly connecting the microelectromechanical component to the contiguous sacrificial region, whereby space is saved again.

Preferably, the silicon layers and the passivation layers are structured such that the contiguous sacrificial region runs, at least in individual silicon layers, in a perpendicular direction relative to the silicon layers. The separation edge can thus at least partly run vertically.

Preferably, the silicon layers and the passivation layers are structured such that the contiguous sacrificial region essentially has the same diameter in all silicon layers. Alternatively, the silicon layers and the passivation layers are structured such that the contiguous sacrificial region at least partly has a varying diameter.

The present invention also relates to a microelectromechanical component which in particular is manufactured according to the method described above. According to an example embodiment of the present invention, the microelectromechanical component comprises at least a first silicon layer and a second silicon layer arranged on the first silicon layer. The microelectromechanical component has, in the second silicon layer, an at least partly outwardly protruding first frame region and, in the first silicon layer, a step-shaped second frame region which in particular likewise at least partly outwardly protrudes. The frame regions serve in particular as engagement regions for a tool which engages with the microelectromechanical component. Preferably, the microelectromechanical component is in the form of a micromirror array. Alternatively, it is at least one microelectromechanical sensor or a sensor arrangement. The micromechanical component may also be a MEMS actuator or a relay.

### BRIEF DESCRIPTION OF THE DRAWINGS

FIG. 1 shows a method for manufacturing a microelectromechanical component, according to an example embodiment of the present invention.

FIGS. 2A and 2B show different embodiments for producing a separation edge, according to an example embodiment of the present invention.

FIG. 3 shows the placement of multiple structurally identical micromirror arrays as microelectromechanical components with respect to each other on a substrate, according to an example embodiment of the present invention.

### DETAILED DESCRIPTION OF EXAMPLE EMBODIMENTS

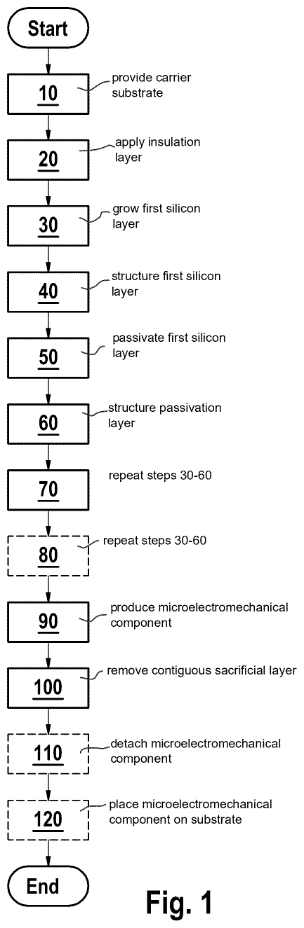

FIG. 1 shows a method for manufacturing a microelectromechanical component, in particular a semiconductor component, in the form of a flowchart. Here, in a method step 10, a carrier substrate having a first surface is provided. In particular, the microelectromechanical component is a micromirror array. In a subsequent method step 20, an insulation layer is applied to the first surface. In a method step 30 following the method step 20, a first silicon layer grows, in particular epitaxially, on the insulation layer. In a further method step 40, the first silicon layer is structured in order to form at least two first peripherally extending trenches in the first silicon layer. Furthermore, in a method step 50, the first silicon layer is passivated. In this method step, the first trenches are filled and a first passivation layer is formed on a side facing away from the first surface. In a subsequent method step 60, the first passivation layer is structured. In this method step, a first peripherally extending sacrificial region is formed in the first silicon layer between the first trenches. The first sacrificial region is free of the first passivation layer, at least in places, on a side facing away from the carrier substrate. In a method step 70 following the method step 60, the method steps 30 to 60 are repeated with the growing, in particular epitaxial growing, structuring and passivating of an additional second silicon layer on the first silicon layer, so that two second peripherally extending trenches filled with a second passivation layer are produced and a second sacrificial region between the second trenches is produced. All sacrificial regions, in particular the first sacrificial region and the second sacrificial region, form a contiguous, in particular common, sacrificial region. In a method step 90 following the method step 70, the microelectromechanical component is produced within a functional region of the silicon layers which is at least partly surrounded by the contiguous sacrificial region. Optionally, it is provided here that the microelectromechanical component is produced at least in part by structuring and passivating at least one of the silicon layers, as well as structuring at least one of the associated passivation layers and removing the sacrificial regions formed. Optionally, it is further provided that the microelectromechanical component is produced such that it is at least partly directly connected to the contiguous sacrificial region. In a method step 100 following the method step 90, the contiguous sacrificial region is removed so that the microelectromechanical component is at least partly detached from the silicon layers, in particular on the opposite side of the contiguous sacrificial region. Optionally, it is provided in this context that the passivation layers and silicon layers are structured such that, after the contiguous sacrificial region has been removed, the microelectromechanical component is partly connected, by means of at least one bridge, to the silicon layers surrounding the microelectromechanical component. Alternatively, the passivation layers and silicon layers are structured such that, after the contiguous sacrificial region has been removed, the microelectromechanical component is completely detached from the silicon layers surrounding the microelectromechanical component.

In an optional, method step 80 following the method step 70, the method steps 30 to 60 are repeated at least once with the growing, in particular epitaxial growing, structuring and passivating of at least one additional, in particular third, silicon layer on the first silicon layer and the second silicon layer, so that at least two additional, in particular third, peripherally extending trenches filled with at least one additional, in particular third, passivation layer are produced and at least one additional, in particular third, sacrificial region is produced.

Furthermore, the silicon layers and the passivation layers are optionally structured such that at least one of the sacrificial regions, in particular first, second or additional sacrificial regions, has a main extension plane in the longitudinal direction and at least partly overlaps with the silicon layer lying therebelow and/or the silicon layer lying thereabove. Furthermore, the silicon layers and the passivation layers are optionally structured in this context such that the at least one sacrificial region having the main extension plane in the longitudinal direction changes direction, in particular by 180°, relative to the microelectromechanical component after a first part, in particular after half, of the peripheral extent, in particular around the microelectromechanical component, so that, after the contiguous sacrificial region has been removed, the microelectromechanical component has, in the first part of the peripheral extent, an outwardly protruding first frame region and, in a second part of the peripheral extent, in particular around the microelectromechanical component, a step-shaped second frame region. Furthermore, it is also optionally provided in a method step 110 following the method step 100 that the microelectromechanical component is detached from the silicon layers surrounding the microelectromechanical component and, by means of a tool which engages with the first frame region and the second frame region of the microelectromechanical component, the second frame region being arranged at a different height than the first frame region, is placed on a substrate. The tool is in particular a vacuum gripper. In a further optional method step 120 following the method step 110, the microelectromechanical component is placed on the substrate relative to a structurally identical second micromechanical component such that the frame regions, in particular in each case a first frame region with a second frame region, of the two microelectromechanical components at least partly overlap.

Optionally, the silicon layers and the passivation layers are structured such that the contiguous sacrificial region runs, at least in individual silicon layers, in a perpendicular direction relative to the silicon layers, in particular in a perpendicular direction relative to a main extension plane of the silicon layers.

Furthermore, the silicon layers and the passivation layers are optionally structured such that the contiguous sacrificial region essentially has the same diameter in all silicon layers. Alternatively, the silicon layers and the passivation layers are structured such that the contiguous sacrificial region at least partly has a varying diameter.

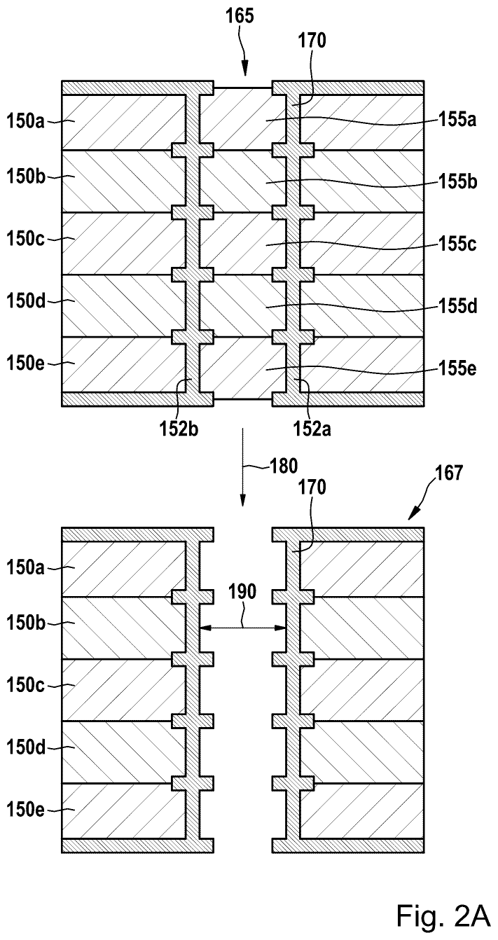

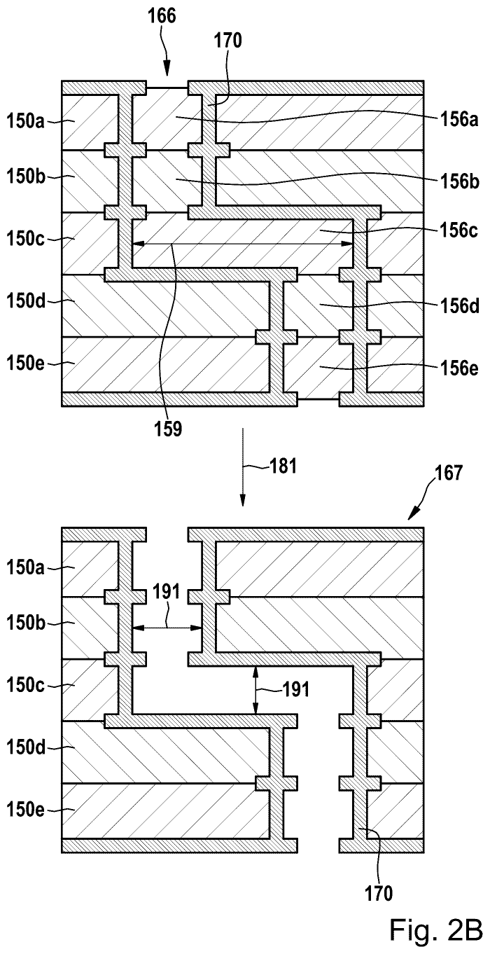

FIG. 2A shows a cross-section of a first embodiment for producing a separation edge of a microelectromechanical component not shown here. Here, a layer stack composed of a first silicon layer 150e, a second silicon layer 150d grown, in particular epitaxially, on the first silicon layer, and further silicon layers 150a to 150c grown, in particular epitaxially, on the second silicon layer 150d is shown. The first silicon layer 150e has two first peripherally extending trenches 152a and 152b, which extend through the first silicon layer 150e. These two first peripherally extending trenches 152a and 152b are filled with a first passivation layer 170 and the first passivation layer 170 also extends partly on a side of the first silicon layer 150e facing the second silicon layer 150d. A first peripherally extending sacrificial region 155e is formed between the first trenches 152a and 152b. The first sacrificial region 155e is largely free of the first passivation layer on a side facing the second silicon layer 150d. The second silicon layer 150d and the further silicon layers 150a to 150c, as well as their associated passivation layers, are also structured like the first silicon layer 150a. Further individual peripherally extending sacrificial regions 155a to 155d are produced between the respective peripherally extending trenches of the silicon layers 150a to 150d. All sacrificial regions 155a to 155e form a contiguous, in particular common, sacrificial region 165. In this embodiment, the contiguous sacrificial region 165 runs in a perpendicular direction relative to the silicon layers 150a to 150d. In a subsequent method step 180, the contiguous sacrificial region 165 is removed so that the microelectromechanical component (not shown here) within a functional region 167 at least partly surrounded by the contiguous sacrificial region is completely detached from the silicon layers 150a to 150e, in particular on the opposite side of the contiguous sacrificial region 165, and thus separated.

The diameter 190 of the removed contiguous sacrificial region 165 essentially has the same diameter in all silicon layers 150a to 150e.

FIG. 2B shows a layer stack having the silicon layers 150a to 150e, in which layer stack, unlike in FIG. 2A, one of the sacrificial regions 156c has a main extension plane in the longitudinal direction 159 and partly overlaps with the silicon layer 150d lying therebelow and the silicon layer 150b lying thereabove. Thus, in the associated silicon layer 150c, the contiguous sacrificial region 166 composed of the individual sacrificial regions 156a to 156e runs parallel to a main extension plane of the silicon layers 150a to 150e. In a subsequent method step 181, the contiguous sacrificial region 166 is removed so that the microelectromechanical component (not shown here) within the functional region 167 at least partly surrounded by the contiguous sacrificial region 166 is completely detached from the silicon layers 150a to 150e, in particular on the opposite side of the contiguous sacrificial region 166, and thus separated. Here as well, the diameter 191 of the removed contiguous sacrificial region 166 essentially has the same diameter in all silicon layers 150a to 150e.

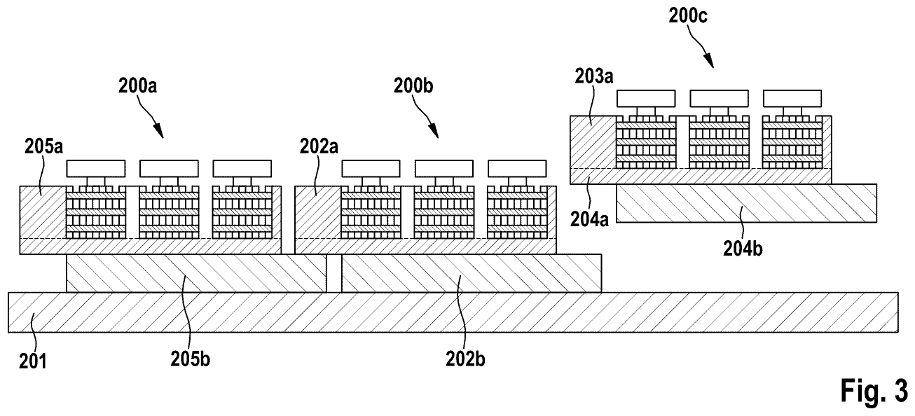

FIG. 3 shows the placement of multiple structurally identical micromirror arrays as microelectromechanical components 200a, 200b and 200c with respect to each other on a substrate 201. The micromirror arrays as microelectromechanical components 200a, 200b and 200c have an outwardly protruding first frame region 202a, 203a and 205a and a step-shaped second frame region 202b, 203b and 205b. The first frame regions 202a, 203a and 205a are arranged at a different height, in particular vertical height, than the second frame regions 202b, 203b and 205b. The micromirror arrays as microelectromechanical components 200a, 200b and 200c are configured such that the micromirror arrays have no outer frame region on the side of the second frame region 202b, 203b and 205b at the same height, in particular of the micromirror arrays. A tool (not shown here), which in particular is in the form of a vacuum gripper, engages with the first frame region 202a, 203a and 205a and the second frame region 202b, 203b and 205b of a micromirror array and places the micromirror arrays relative to each other on the substrate 201 such that, in general, a first frame region 202a, 203a and 205a overlaps with a second frame region of an adjacent micromirror array. This leads to an increase in the optical fill factor of the micromirror arrays arranged adjacent to each other on the substrate 201.

1-15. (canceled)

16. A method for manufacturing a microelectromechanical component including a semiconductor component, the method comprising the following steps:
providing a carrier substrate having a first surface;
applying an insulation layer to the first surface;
growing epitaxially, a first silicon layer on the insulation layer;
structuring the first silicon layer to form at least two first peripherally extending trenches in the first silicon layer, wherein the first trenches extend through the first silicon layer at least in places;
passivating the first silicon layer, wherein the first trenches are filled and a first passivation layer is formed on a side facing away from the first surface;
structuring the first passivation layer, wherein a first peripherally extending sacrificial region is formed in the first silicon layer between the first trenches, and the first sacrificial region is free of the first passivation layer, at least in places, on a side facing away from the carrier substrate; and
carrying out repeated epitaxial growing, structuring, and passivating of an additional second silicon layer on the first silicon layer, so that two second peripherally extending trenches filled with a second passivation layer are produced and a second sacrificial region between the second trenches is produced,
wherein the first sacrificial region and the second sacrificial region form a contiguous, common, sacrificial region,
producing the microelectromechanical component within a functional region of the first and second silicon layers which is at least partly surrounded by the contiguous sacrificial region; and
removing the contiguous sacrificial region so that the microelectromechanical component is at least partly detached from the first and second silicon layers, in particular on an opposite side of the contiguous sacrificial region.

17. The method according to claim 16, further comprising:
carrying out repeated epitaxial growing, structuring, and passivating of at least one additional third, silicon layer on the first silicon layer and the second silicon layer, so that at least two additional third, peripherally extending trenches filled with at least one additional third passivation layer are produced and at least one additional third sacrificial region is produced.

18. The method according to claim 16, wherein the first and second silicon layers and the first and second passivation layers are structured such that at least one of the first and second sacrificial regions has a main extension plane in a longitudinal direction and at least partly overlaps with a silicon layer lying therebelow and/or a layer lying thereabove.

19. The method according to claim 18, wherein the first and second silicon layers and the fist and second passivation layers are structured such that the at least one of the first and second sacrificial regions having the main extension plane in the longitudinal direction changes direction by 180° relative to the microelectromechanical component after a first part of a peripheral extent, around the microelectromechanical component, so that, after the contiguous sacrificial region has been removed, the microelectromechanical component has, in the first part of the peripheral extent, an outwardly protruding first frame region, and, in a second part of the peripheral extent, around the microelectromechanical component, a step-shaped second frame region.

20. The method according to claim 19, wherein the microelectromechanical component is detached from the first and second silicon layers surrounding the microelectromechanical component, and, using a tool, which engages with the first frame region and the second frame region of the microelectromechanical component, the second frame region being arranged at a different height than the first frame region, is placed on a substrate.

21. The method according to claim 20, wherein the microelectromechanical component is placed on the substrate relative to a structurally identical second micromechanical component such that the first frame region of each of the microelectromechanical components at least partially overlaps with the second frame region of the other of the microelectromechanical component.

22. The method according to claim 16, wherein the microelectromechanical component is produced at least in part by structuring and passivating at least one of the first and second silicon layers, as well as structuring at least one of the first and second passivation layers and removing the first and second sacrificial regions of the microelectromechanical component which are formed.

23. The method according to claim 16, wherein the first and second passivation layers and the first and second silicon layers are structured such that, after the contiguous sacrificial region has been removed, the microelectromechanical component is partly connected, by at least one bridge, to the first and second silicon layers surrounding the microelectromechanical component.

24. The method according to claim 16, wherein the first and second passivation layers and the first and second silicon layers are structured such that, after the contiguous sacrificial region has been removed, the microelectromechanical component is completely detached from the first and second silicon layers surrounding the microelectromechanical component.

25. The method according to claim 16, wherein the microelectromechanical component is produced such that the microelectromechanical component is at least partly directly connected to the contiguous sacrificial region.

26. The method according to claim 16, wherein the first and second silicon and the first and second passivation layers are structured such that the contiguous sacrificial region runs, at least in individual ones of the first and second silicon layers, in a perpendicular direction relative to the first and second silicon layers.

27. The method according to claim 16, wherein the first and second silicon layers and the first and second passivation layers are structured such that the contiguous sacrificial region has the same diameter in both of the first and second silicon layers.

28. The method according to claim 16, wherein the first and second silicon layers and the first and second passivation layers are structured such that the contiguous sacrificial region at least partly has a varying diameter.

29. A microelectromechanical component, comprising:
a first silicon layer and a second silicon layer arranged on the first silicon layer,
wherein the microelectromechanical component has, in the second silicon layer, an at least partly outwardly protruding first frame region, and, in the first silicon layer, a step-shaped second frame region which at least partly outwardly protrudes.

30. The microelectromechanical component according to claim 29, wherein the microelectromechanical component is a micromirror array.

31. The microelectromechanical component according to claim 29, wherein the microelectromechanical component is formed by the following steps:
providing a carrier substrate having a first surface;
applying an insulation layer to the first surface;
growing epitaxially, the first silicon layer on the insulation layer;
structuring the first silicon layer to form at least two first peripherally extending trenches in the first silicon layer, wherein the first trenches extend through the first silicon layer at least in places;
passivating the first silicon layer, wherein the first trenches are filled and a first passivation layer is formed on a side facing away from the first surface;
structuring the first passivation layer, wherein a first peripherally extending sacrificial region is formed in the first silicon layer between the first trenches, and the first sacrificial region is free of the first passivation layer, at least in places, on a side facing away from the carrier substrate; and
